(19) United States
(12) Patent Application Publication
(10) Pub. No.: US 2011/0316531 A1
(43) Pub. Date: Dec. 29, 2011

(54) DEVICE FOR MEASURING THE DIRECTION AND/OR STRENGTH OF A MAGNETIC FIELD

(76) Inventor: Frank Schatz, Kornwestheim (DE)

(21) Appl. No.: 13/123,843

(22) PCT Filed: Aug. 13, 2009
(86) PCT No.: PCT/EP2009/060490

§ 371 Date: Sep. 9, 2011

(30) Foreign Application Priority Data
Oct. 13, 2008 (DE) 10 2008 042 800.0

(51) Int. Cl. G01R 33/02

(52) U.S. Cl. 324/244

(57) ABSTRACT

A device for measuring the direction and/or strength of a magnetic field is described which includes a first sensor for detecting a first component of the magnetic field in a first spatial direction, a second sensor for detecting a second component of the magnetic field in a second spatial direction, and a third sensor for detecting a third component of the magnetic field in a third spatial direction, the first sensor containing at least one Hall sensor and the second and/or third sensors containing at least one fluxgate sensor.

### FIELD OF THE INVENTION

The present invention relates to a device for measuring the direction and/or strength of a magnetic field, including a first sensor for detecting a first component of the magnetic field in a first spatial direction, a second sensor for detecting a second component of the magnetic field in a second spatial direction, and a third sensor for detecting a third component of the magnetic field in a third spatial direction.

### BACKGROUND INFORMATION

Devices of the type described above may be used to measure the direction and strength of the earth's magnetic field, for example. The measured direction of the earth's magnetic field may be visualized for the user in the form of a digital compass, for example. In addition, the measured values may be used by a navigation system or an autopilot to control a vehicle, an aircraft, or a boat.

For three-dimensional detection of the direction of a magnetic field, for example, the earth's magnetic field, all three spatial directions must be detected. Conventionally, a Hall sensor, for example, is used for this purpose. However, the disadvantage of this approach is that only one field component perpendicular to the plane of the sensor may be determined with sufficient accuracy. In contrast, two field components in the plane of the sensor cannot be measured with sufficient accuracy. Detecting all three spatial directions of a magnetic field thus requires a plurality of Hall sensors, each of which is positioned orthogonally to the others.

It is therefore complex to manufacture a device for three-dimensional measurement of the direction and/or strength of a magnetic field. In addition, such a conventional device requires a comparatively large installation space.

An object of the present invention is to provide a device for three-dimensional measurement of the direction and/or strength of a magnetic field, which is small in size and is manufactured easily and inexpensively.

This object may be achieved according to an example embodiment the present invention by providing a device for measuring the direction and/or strength of a magnetic field, including a first sensor for detection of a first component of the magnetic field in a first spatial direction, a second sensor for detecting a second component of the magnetic field in a second spatial direction, and a third sensor for detecting a third component of the magnetic field in a third spatial direction, the first sensor containing at least one Hall sensor, and the second and/or third sensor containing at least one fluxgate sensor.

In accordance with the present invention, at least one Hall sensor may be combined with at least one fluxgate sensor. The Hall sensor detects a magnetic field component perpendicular to the sensor surface having maximal sensitivity. In contrast, a fluxgate sensor is designed to detect a magnetic field component within the plane of the sensor. Thus, at least one Hall sensor and at least one fluxgate sensor may be situated in a space-saving manner in a plane on a single semiconductor substrate, for example. If at least two fluxgate sensors are provided forming a right angle, for example, a magnetic field may be detected in all three directions in space without requiring a second semiconductor substrate at a right angle to the first semiconductor substrate. The example sensor proposed in accordance with the present invention thus saves on installation height and is simpler to manufacture.

In a preferred refinement of the present invention, the semiconductor substrate containing the Hall sensor and the fluxgate sensors may include at least one additional component. For example, power may be supplied to the sensors or a measured value may be detected via such additional components. In addition, the components may be used to perform a plausibility check, amplification, discrimination, or digitization of the output values of the sensors.

Another preferred embodiment of the present invention may provide for multiple sensors to be provided for each spatial direction to thereby increase the reliability of the device through redundant measurement.

In a refinement of the present invention, at least one fluxgate sensor is produced on the semiconductor substrate in planar coil technology or 3D microcoil technology. The fluxgate sensor may be situated in one or two metallic planes, for example. In this way, the fluxgate sensor together with the Hall sensor and additional electronic components may be produced on the semiconductor substrate in one operation.

The example device proposed according to the present invention may be used in particular to measure the direction and/or strength of the earth's magnetic field. The device is suitable for consumer electronics such as cellular telephones, PDAs or navigation devices in particular.

### BRIEF DESCRIPTION OF THE DRAWINGS

The present invention is described in greater detail below on the basis of one exemplary embodiment without restricting the general idea of the present invention.

FIG. 1 shows the placement of the components on a substrate.

### DETAILED DESCRIPTION OF EXAMPLE EMBODIMENTS

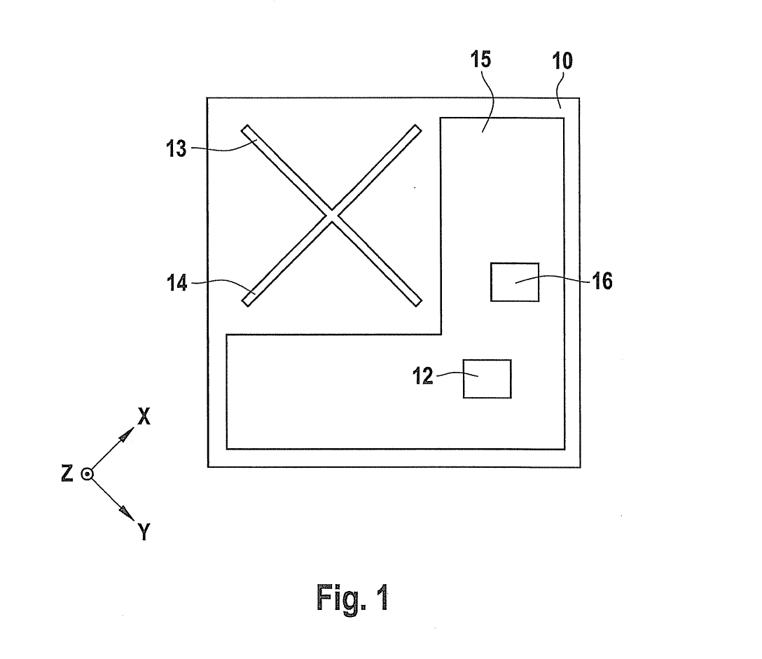

The example device shown in FIG. 1 is situated on a substrate 10. Substrate 10 includes, for example, a semiconductor substrate, in particular a silicon substrate. To adjust a predefinable conductivity, semiconductor substrate 10′ may be provided with a dopant. The surface of substrate 10 may be coated with an insulator to prevent an electric short circuit between substrate 10 and the components situated on its surface. The insulator may contain in particular silicon nitride, silicon oxide, or silicon oxynitride.

A Hall sensor 12 is situated on the surface of substrate 10. Hall sensor 12 includes a spatially delimited region containing a semiconductor material having a high charge carrier mobility. During operation of the sensor, an electric field is applied along one direction of Hall sensor 12, causing an electric current to flow through the sensor. In the presence of a magnetic field acting in a direction perpendicular to the surface of substrate 10, an electric voltage which rises with the field strength of the magnetic field is measurable on Hall sensor 12 in a direction orthogonal to the electric current flow. Hall sensor 12 thus functions to measure the field component of the magnetic field, which is perpendicular to the surface of semiconductor substrate 10.

Hall sensor 12 may also be manufactured by structuring semiconductor substrate 10 in a conventional manner. In another specific embodiment of the present invention, the material of Hall sensor 12 may be deposited from the gas phase on the surface of the semiconductor substrate and then structured and provided with metallic terminal contacts.

Since Hall sensor 12 is provided to detect a magnetic field or a magnetic field component z, which acts generally perpendicular to the surface of substrate 10, two fluxgate sensors 13 and 14 are provided to detect a magnetic field or a magnetic field component in the x-y plane of substrate 10. To do so, first fluxgate sensor 13 and second fluxgate sensor 14 are approximately orthogonal to one another. Together with Hall sensor 12, three components of a magnetic field may thus be determined in all three spatial directions. Therefore, the orientation of the magnetic field in space may be determined.

Each fluxgate sensor 13 and 14 includes at least one coil core, which is preferably made of a soft magnetic material. Exciter coils and detection coils are provided around the coil core. Thus, a magnetic field or a magnetic field component in direction x may be determined with the aid of fluxgate sensor 13 by cyclically inducing a magnetic field in the coil core via the exciter coil and in-phase sampling of the induction signal in the detection coil. In the same way, fluxgate sensor 14 is used to determine a magnetic field or a magnetic field component in direction y.

Fluxgate sensors 13 and 14 may be manufactured as micromechanical components, for example, and then attached to the surface of substrate 10 by adhesion, welding or bonding.

In this specific embodiment, the substrate may be formed by a ceramic or a circuit board, for example.

In another specific embodiment of the present invention, the coil windings and the coil cores of fluxgate sensors 13 and 14 may be deposited from the gas phase on the surface of semiconductor substrate 10 and then structured. This deposition may be accomplished by vapor deposition, sputtering, chemical vapor deposition, or physical vapor deposition, for example. The structuring may include an etching step, for example, where partial areas of the substrate surface are protected from etching attack by photoresists or hard masks. Insulating layers may be provided between the coil cores and the coil windings in some cases. These layers are also preferably deposited in a gas-phase process and then structured. In this way, the device for measuring the direction and/or strength of a magnetic field may be manufactured easily by the conventional CMOS process steps.

In addition, the surface of semiconductor substrate 10 includes a region 15, which contains electronic components for triggering and for data acquisition of the three magnetic field sensors 12, 13 and 14. Region 15 includes, for example, a current regulator, using which a predefinable longitudinal current may be generated through Hall sensor 12. In addition, region 15 may include AC voltage sources, which provide a coil current for generating an alternating magnetic field in the cores of fluxgate sensors 13 and 14. Finally, region 15 may include evaluation circuits 16 as electric components, which read out the Hall voltage of Hall sensor 12 and the signal voltages induced in the measuring coils of fluxgate sensors 13 and 14.

In some cases, region 15 may also include additional circuits for digitizing the signals, for amplification, for discrimination or for a plausibility check, for example. In some cases, circuits for a sensor self-test may also be provided. Finally, region 15 of semiconductor substrate 10 includes bond pads, with the aid of which an operating voltage may be applied to the sensor elements, as well as additional bond pads, by which the measured values may be read out.

As a result, the example embodiment of the present invention includes a magnetic field sensor for three spatial directions in which all sensors for all spatial directions are situated in one plane on the surface of a substrate 10. The example sensor according to the present invention therefore has a smaller total height. In addition, the example sensor may be produced more easily because it is no longer necessary to provide multiple Hall sensors 12 on multiple substrates in different orthogonal directions in order to measure magnetic fields in multiple directions orthogonal to one another.

Those skilled in the art will of course be aware of the fact that the present invention is not limited to the exemplary embodiment presented here. Instead, in implementation of the present invention, modifications and changes may be made without significantly altering the present invention per se. The preceding description is therefore to be regarded as explanatory rather than restrictive.

1-9. (canceled)

10. A device for measuring at least one of a direction and a strength of a magnetic field, comprising:
a first sensor to detect a first component of the magnetic field in a first spatial direction;
a second sensor to detect a second component of the magnetic field in a second spatial direction; and
a third sensor to detect a third component of the magnetic field in a third spatial direction;
wherein the first sensor includes at least one Hall sensor, and at least one of the second and third sensor includes at least one fluxgate sensor.

11. The device as recited in claim 10, wherein at least the first, second and third sensors are situated on a substrate.

12. The device as recited in claim 11, wherein at least one additional electronic component is situated on the substrate.

13. The device as recited in claim 11, wherein the substrate is a semiconductor substrate, and the first, second and third sensors are manufactured by a CMOS process.

14. The device as recited in claim 10, wherein at least one of the fluxgate sensors is formed by one of planar coil technology or 3D microcoil technology.

15. The device as recited in claim 10, wherein at least one of the fluxgate sensors includes a core which is formed by gas-phase deposition and subsequent structuring.

16. The device as recited in claim 10, wherein the device includes at least two fluxgate sensors, the at least two fluxgate sensors to measure a magnetic field in mutually orthogonal directions.

17. A cellular telephone, comprising:
cellular telephone components; and
a device for measuring at least one of a direction and strength of a magnetic field, the device including a first sensor to detect a first component of the magnetic field in a first spatial direction, a second sensor to detect a second component of the magnetic field in a second spatial direction, and a third sensor to detect a third component of the magnetic field in a third spatial direction, wherein the first sensor includes at least one Hall sensor, and at least one of the second and third sensor includes at least one fluxgate sensor.

18. A method of using a device for measuring at least one of a direction and strength of the Earth's magnetic field, the method comprising:
providing the device, the device including a first sensor to detect a first component of the magnetic field in a first spatial direction, a second sensor to detect a second component of the magnetic field in a second spatial direction, and a third sensor to detect a third component of the magnetic field in a third spatial direction, wherein the first sensor includes at least one Hall sensor, and at least one of the second and third sensor includes at least one fluxgate sensor; and
using the device to measure at least one of the direction and the strength of the Earth's magnetic field.
